(19) United States
(12) Patent Application Publication
(10) Pub. No.: US 2026/0020499 A1
(43) Pub. Date: Jan. 15, 2026

(54) PIEZOELECTRIC RESONATOR DEVICE

(71) Applicant: DAISHINKU CORPORATION, Kakogawa-shi, Hyogo (JP)

(72) Inventor: Hiroki FUJIWARA, Kakogawa-shi (JP)

(73) Assignee: DAISHINKU CORPORATION, Kakogawa-shi, Hyogo (JP)

(21) Appl. No.: 18/995,881

(22) PCT Filed: Jul. 24, 2023
(86) PCT No.: PCT/JP2023/027051

§ 371 Date: Jan. 17, 2025

(30) Foreign Application Priority Data
Jul. 29, 2022 (JP) 2022-121680

(51) Int. Cl. H10N 30/87; H10N 30/88

(52) U.S. Cl. CPC H10N 30/87; H10N 30/88

(57) ABSTRACT

A piezoelectric resonator device according to one or more embodiments may include a crystal resonator plate including first and second excitation electrodes sandwiched by first and second sealing members placed respectively above and below the crystal resonator plate so as to bond respective sealing parts to each other. The first sealing member includes a fourth through hole penetrating between a first main surface and a second main surface. An opening area of an opening in the first main surface side of the fourth through hole is larger than an opening area of an opening in the second main surface side. The width of a sealing-surface-side opening surrounding electrode is larger than the width of an outer-surface-side opening surrounding electrode in the Z′ axis direction.

### TECHNICAL FIELD

The present invention relates to a piezoelectric resonator device.

BACKGROUND ART

Recently, in various electronic devices, the operating frequencies have increased and the package sizes (especially the heights) have been decreased. According to such an increase in operating frequency and a reduction in package size, there is also a need for piezoelectric resonator devices (such as a crystal resonator and a crystal oscillator) to be adaptable to the increase in operating frequency and the reduction in package size.

In this type of piezoelectric resonator devices, a housing is formed by a package having a substantially rectangular parallelepiped shape. The package has, for example, a configuration in which a crystal resonator plate having excitation electrodes formed thereon is sandwiched by crystal sealing plates placed respectively above and below the crystal resonator plate. The inside (internal space) of the package is hermetically sealed by bonding respective sealing parts to each other (for example, see Patent Document 1).

### PRIOR ART DOCUMENTS

### Patent Documents

Patent Document 1: JP 2010-252051 A

### SUMMARY OF THE INVENTION

### Problem to Be Solved by the Invention

In the piezoelectric resonator device as described above, through holes are formed in the crystal sealing plate so as to penetrate between the outer surface side and the sealing surface side thereof, and conduction paths to the excitation electrodes are formed by: inner wall electrodes formed on inner wall surfaces of the through holes; and opening surrounding electrodes formed on the peripheries of openings of the through holes. The opening surrounding electrode serves not only as the conduction path, but also as a seal to maintain hermeticity from the external environment by making closely contact with and being bonded to the electrode formed on the crystal resonator plate.

The inner wall electrode and the opening surrounding electrode of the through hole as described above has a configuration in which a front surface main electrode layer made of, for example, Au is laminated as an upper layer on a base electrode layer made of, for example, Ti. However, since the through hole formed in the crystal sealing plate provided on the upper side of the crystal resonator plate is exposed to the outside, water or the like may enter the through hole through its opening, which may corrode the base electrode layer (Ti layer) of each or either of the inner wall electrode and the opening surrounding electrode. In hot and humid conditions and/or for a long time, the corrosion of the base electrode layer of the inner wall electrode and/or the opening surrounding electrode proceeds to reach the internal space, which may degrade hermeticity of the internal space of the package.

The present invention was made in consideration of the above circumstances, an object of which is to provide a piezoelectric resonator device capable of reducing progression of corrosion of an opening surrounding electrode of a through hole.

### Means for Solving the Problem

As the means for solving the above problem, the present invention provides the configuration below. That is, a piezoelectric resonator device is provided, in which a crystal resonator plate having excitation electrodes thereon is sandwiched by crystal sealing plates placed respectively above and below the crystal resonator plate so as to bond and hermetically seal respective sealing parts to each other. Each or any of the crystal sealing plates includes a through hole penetrating between an outer surface side and a sealing surface side. The through hole is provided with: an inner wall electrode formed on an inner wall surface; an outer-surface-side opening surrounding electrode formed on a periphery of an opening in the outer surface side; and a sealing-surface-side opening surrounding electrode formed on a periphery of an opening in the sealing surface side. The through hole also includes a hollow penetrating part. An opening area of the opening in the outer surface side of the through hole is larger than an opening area of the opening in the sealing surface side. A width of the sealing-surface-side opening surrounding electrode is larger than a width of the outer-surface-side opening surrounding electrode in a Z′ axis direction.

With the above-described configuration, since the width of the sealing-surface-side opening surrounding electrode of the through hole is larger than the width of the outer-surface-side opening surrounding electrode in the Z′ axis direction, it is possible to prevent the corrosion of the sealing-surface-side opening surrounding electrode from progressing compared to the case in which the width of the outer-surface-side opening surrounding electrode is the same as the width of the sealing-surface-side opening surrounding electrode. Thus, the hermeticity of the internal space of the package can be maintained as much as possible. Furthermore, since the width of the outer-surface-side opening surrounding electrode of the through hole is smaller than the width of the sealing-surface-side opening surrounding electrode, it is possible to easily design the wiring on the outer surface side of the crystal sealing plate compared to the case in which the width of the outer-surface-side opening surrounding electrode is the same as the width of the sealing-surface-side opening surrounding electrode, which contributes to the miniaturization of the package.

Here, if the opening area of the opening in the outer surface side of the through hole is the same as the opening area of the opening in the sealing surface side, it is necessary to increase the total volume of the components including the through hole and the surrounding electrodes in order to ensure the width of the sealing-surface-side opening surrounding electrode. In contrast to the above, in the above-described configuration, the opening areas of the openings of the through hole have a magnitude relationship. That is, the opening area of the opening in the sealing surface side is smaller than the opening area of the opening in the outer surface side. Thus, there is an enough space around the through hole for easily ensuring the width of the sealing-surface-side opening surrounding electrode, which leads to a configuration advantageous for the miniaturization without unnecessarily increasing the total volume of the components including the through hole and the surrounding electrodes. As a result, since the width of the sealing-surface-side opening surrounding electrode can be increased, the area of the sealing part by the sealing-surface-side opening surrounding electrode does not become too small. Therefore, the area can be stably ensured, and thus, the corrosion can be prevented from progressing compared to the case in which the area of the sealing part cannot be ensured.

When the wet etching is performed to the AT-cut crystal resonator plate, the through hole is inclined in the Z′ axis direction because of crystal anisotropy, which sometimes causes difficulty in sufficiently ensuring the width of the surrounding electrode as a result of deviation from the design. In contrast, in the above-described configuration, since the sealing-surface-side opening surrounding electrode is largely formed in the Z′ axis direction, it is possible to easily handle the above problem, which contributes to stability of hermeticity and of conductivity.

In the above-described configuration, it is preferable that the width of the sealing-surface-side opening surrounding electrode is larger than the width of the outer-surface-side opening surrounding electrode in the X axis direction. In this way, since the width of the sealing-surface-side opening surrounding electrode of the through hole is larger than the width of the outer-surface-side opening surrounding electrode not only in the Z′ axis direction but also in the X axis direction, it is possible to prevent the corrosion of the sealing-surface-side opening surrounding electrode from progressing compared to the case in which the width of the outer-surface-side opening surrounding electrode is the same as the width of the sealing-surface-side opening surrounding electrode. Thus, the hermeticity of the internal space of the package can be maintained as much as possible.

Also, the present invention provides a piezoelectric resonator device in which a crystal resonator plate having excitation electrodes thereon is sandwiched by crystal sealing plates placed respectively above and below the crystal resonator plate so as to bond and hermetically seal respective sealing parts to each other. Each or any of the crystal sealing plate includes a through hole penetrating between an outer surface side and a sealing surface side. The through hole is provided with: an inner wall electrode formed on an inner wall surface; an outer-surface-side opening surrounding electrode formed on a periphery of an opening in the outer surface side; and a sealing-surface-side opening surrounding electrode formed on a periphery of an opening in the sealing surface side. The through hole also includes a hollow penetrating part. An opening area of the opening in the outer surface side of the through hole is larger than an opening area of the opening in the sealing surface side. A width of the sealing-surface-side opening surrounding electrode is larger than a width of the outer-surface-side opening surrounding electrode in the X axis direction.

With the above-described configuration, since the width of the sealing-surface-side opening surrounding electrode of the through hole is larger than the width of the outer-surface-side opening surrounding electrode in the X axis direction, it is possible to prevent the corrosion of the sealing-surface-side opening surrounding electrode from progressing compared to the case in which the width of the outer-surface-side opening surrounding electrode is the same as the width of the sealing-surface-side opening surrounding electrode. Thus, the hermeticity of the internal space of the package can be maintained as much as possible. Furthermore, since the width of the outer-surface-side opening surrounding electrode of the through hole is smaller than the width of the sealing-surface-side opening surrounding electrode, it is possible to easily design the wiring on the outer surface side of the crystal sealing plate compared to the case in which the width of the outer-surface-side opening surrounding electrode is the same as the width of the sealing-surface-side opening surrounding electrode, which contributes to the miniaturization of the package.

Here, if the opening area of the opening in the outer surface side of the through hole is the same as the opening area of the opening in the sealing surface side, it is necessary to increase the total volume of the components including the through hole and the surrounding electrodes in order to ensure the width of the sealing-surface-side opening surrounding electrode. In contrast to the above, in the above-described configuration, the opening areas of the openings of the through hole have a magnitude relationship. That is, the opening area of the opening in the sealing surface side is smaller than the opening area of the opening in the outer surface side. Thus, there is an enough space around the through hole for easily ensuring the width of the sealing-surface-side opening surrounding electrode, which leads to a configuration advantageous for the miniaturization without unnecessarily increasing the total volume of the components including the through hole and the surrounding electrodes. As a result, since the width of the sealing-surface-side opening surrounding electrode can be increased, the area of the sealing part by the sealing-surface-side opening surrounding electrode does not become too small. Therefore, the area can be stably ensured, and thus, the corrosion can be prevented from progressing compared to the case in which the area of the sealing part cannot be ensured.

In the above-described configuration, it is preferable that the bonding is Au—Au diffusion bonding, and that the sealing-surface-side opening surrounding electrode includes a front surface main electrode layer made of Au and a base electrode layer made of Ti. Thus, it is possible to prevent the corrosion of the base electrode layer of the sealing-surface-side opening surrounding electrode of the through hole from progressing. Also, the hermeticity of the internal space of the package can be maintained as much as possible. Furthermore, by performing Au—Au diffusion bonding (Au—Au bonding), it is possible to make smaller the gap between the crystal resonator plate and the crystal sealing plate, which contributes to height reduction of the package. In addition, since no gas or the like derived from the adhesive is generated when the bonding is performed, it is possible to stabilize the hermeticity of the internal space of the package, which contributes to reduction of any bad influence on the electrical characteristics of the crystal resonator plate.

The above-described configuration is further characterized in that: a center of the opening in the outer surface side of the through hole is superimposed on a substantial opening end in the sealing surface side, which is opposed to the outer surface side, of the through hole; and a center of the opening in the sealing surface side of the through hole is superimposed on a substantial opening end in the outer surface side, which is opposed to the sealing surface side, of the through hole. In this way, it is possible to reliably form the through hole in the crystal sealing plate by wet etching without unnecessarily increasing the volume of the through hole, which contributes to the miniaturization of the package.

The above-described configuration is further characterized in that: a central opening having the smallest opening cross-sectional area is provided in a central part of the through hole in a thickness direction of the crystal sealing plate; and a center of the opening in the outer surface side of the through hole is superimposed on the central opening while a center of the opening in the sealing surface side of the through hole is superimposed on the central opening. In this way, it is possible to reliably form the through hole in the crystal sealing plate by wet etching without unnecessarily increasing the volume of the through hole, which contributes to the miniaturization of the package. Furthermore, it is possible to prevent break or the like of the following electrodes of the through hole: the inner wall electrode; the outer-surface-side opening surrounding electrode; and the sealing-surface-side opening surrounding electrode.

The above-described configuration is further characterized in that an outer peripheral end of the sealing-surface-side opening surrounding electrode is located outside an opening end in the outer surface side of the through hole. Thus, there is no gap between the sealing members, which leads to more reliable Au—Au bonding and also to stable hermeticity of the internal space of the package.

### Effects of the Invention

With the present invention, since the width of the sealing-surface-side opening surrounding electrode of the through hole is larger than the width of the outer-surface-side opening surrounding electrode, it is possible to prevent the corrosion of the sealing-surface-side opening surrounding electrode from progressing compared to the case in which the width of the outer-surface-side opening surrounding electrode is the same as the width of the sealing-surface-side opening surrounding electrode. Thus, the hermeticity of the internal space of the package can be maintained as much as possible.

### BRIEF DESCRIPTION OF THE DRAWINGS

FIG. 1 is a schematic configuration diagram schematically illustrating a configuration of a crystal oscillator according to an embodiment of the present invention.

FIG. 2 is a schematic plan view illustrating a first main surface of a first sealing member of the crystal oscillator.

FIG. 3 is a schematic plan view illustrating a second main surface of the first sealing member of the crystal oscillator.

FIG. 4 is a schematic plan view illustrating a first main surface of a crystal resonator plate of the crystal oscillator.

FIG. 5 is a schematic plan view illustrating a second main surface of the crystal resonator plate of the crystal oscillator.

FIG. 6 is a schematic plan view illustrating a first main surface of a second sealing member of the crystal oscillator.

FIG. 7 is a schematic plan view illustrating a second main surface of the second sealing member of the crystal oscillator.

FIG. 8 is a diagram illustrating one example of a cross-sectional shape of a fourth through hole formed in the first sealing member.

FIG. 9 is a cross-sectional view taken along line X1-X1 of FIG. 8.

FIG. 10 is a cross-sectional view taken along line X2-X2 of FIG. 8.

FIG. 11 is a diagram for explaining the size and the like of the fourth through hole.

FIG. 12 is a diagram illustrating another cross-sectional shape of the fourth through hole.

FIG. 13 is a schematic plan view illustrating a first main surface of a tuning fork-type crystal resonator plate of a crystal oscillator according to the other embodiment 1.

FIG. 14 is a schematic configuration diagram schematically illustrating a configuration of a crystal oscillator according to the other embodiment 2.

FIG. 15 is a diagram illustrating one example of a cross-sectional shape of a through hole formed in the second sealing member of the crystal resonator of FIG. 14.

### MODE FOR CARRYING OUT THE INVENTION

Hereinafter, an embodiment of the present invention will be described in detail with reference to the drawings. In the following embodiment, the present invention is applied to a crystal oscillator as a crystal resonator device. However, the crystal resonator device to which the present invention is applied is not limited to the crystal oscillator. The present invention may be applied to a crystal resonator.

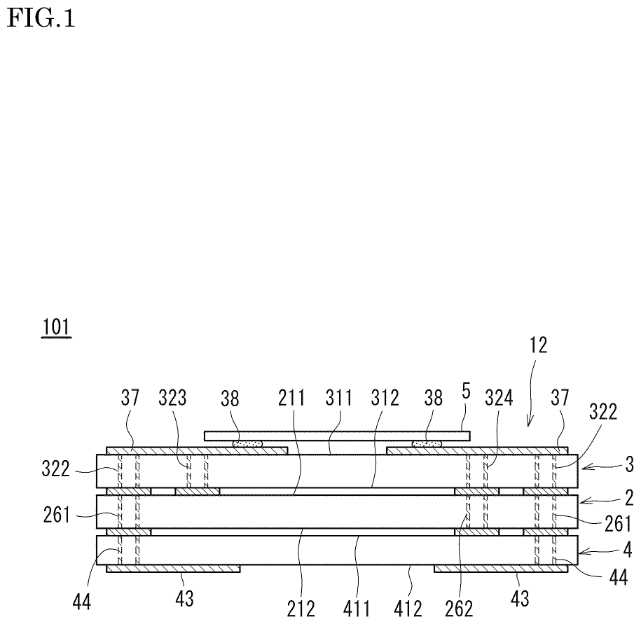

As shown in FIG. 1, a crystal oscillator 101 according to this embodiment includes: a crystal resonator plate 2; a first sealing member 3; a second sealing member 4; and an IC chip 5. In this crystal oscillator 101, the crystal resonator plate 2 is bonded to the first sealing member 3, and furthermore the crystal resonator plate 2 is bonded to the second sealing member 4. Thus, a package 12 having a sandwich structure is formed so as to have a substantially rectangular parallelepiped shape. Also, the IC chip 5 is mounted on a main surface of the first sealing member 3 so as to be opposed to a surface bonded to the crystal resonator plate 2. The IC chip 5 as an electronic component element is a one-chip integrated circuit element constituting, with the crystal resonator plate 2, an oscillation circuit.

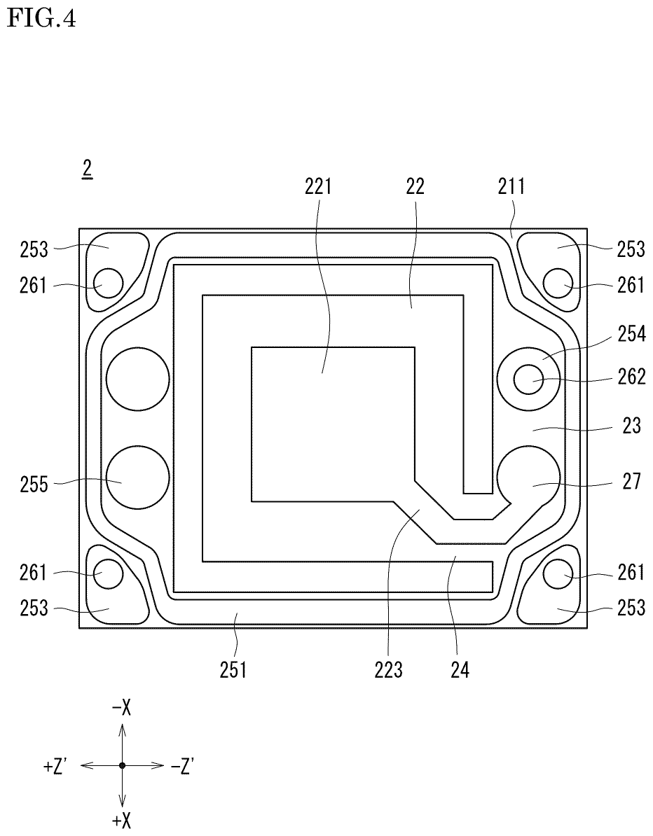

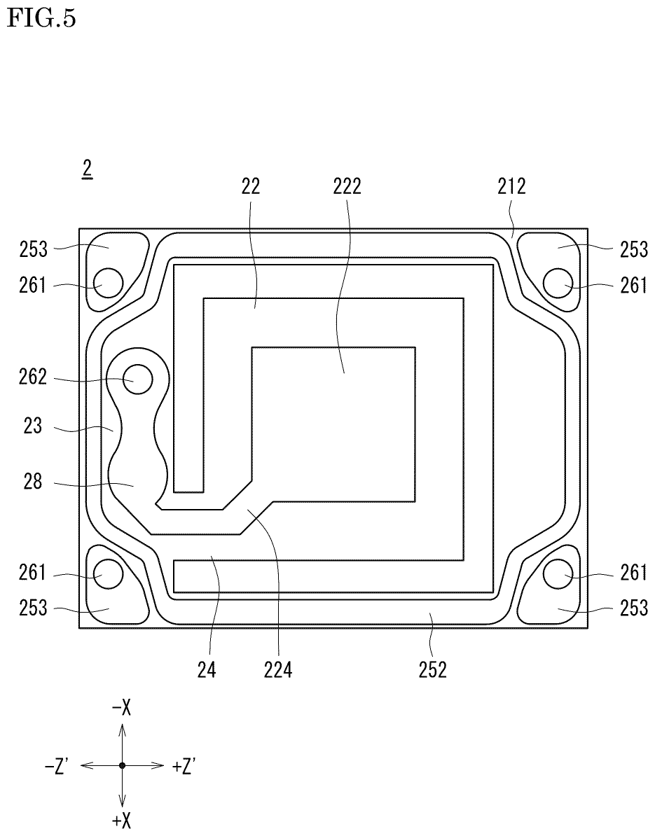

In the crystal resonator plate 2, a first excitation electrode 221 is formed on a first main surface 211 as one main surface while a second excitation electrode 222 is formed on a second main surface 212 as the other main surface. In the crystal oscillator 101, the first sealing member 3 and the second sealing member 4 are bonded respectively to the main surfaces (the first main surface 211 and the second main surface 212) of the crystal resonator plate 2, thus an internal space of the package 12 is formed. In this internal space, a vibrating part 22 (see FIGS. 4 and 5) including the first excitation electrode 221 and the second excitation electrode 222 is hermetically sealed.

The crystal oscillator 101 according to this embodiment has, for example, a package size of 1.0×0.8 mm, which is reduced in size and height. According to the size reduction, no castellation is formed in the package 12. Through holes (described later) are used for conduction between electrodes. If the castellation is used, since it is formed in an outer surface of the package 12, the external size of the package 12 is likely to change, which results in decrease in the mechanical strength. Also, since the castellation is exposed to the outside, the wires may be broken when they unexpectedly make contact with something. However, in this embodiment, the conduction between the electrodes is realized by the through holes. Thus, it is possible to avoid occurrence of the above problems.

Next, the respective components of the above-described crystal oscillator 101 (i.e. the crystal resonator plate 2, the first sealing member 3 and the second sealing member 4) will be described referring to FIGS. 1 to 7. Here, each of the components will be described as a single body without being bonded.

The crystal resonator plate 2 is a piezoelectric substrate made of crystal as shown in FIGS. 4 and 5. Both main surfaces (i.e. the first main surface 211 and the second main surface 212) are formed as smooth flat surfaces (mirror-finished). In this embodiment, an AT-cut crystal plate that causes thickness shear vibration is used as the crystal resonator plate 2. In the crystal resonator plate 2 shown in FIGS. 4 and 5, each of the main surfaces 211 and 212 of the crystal resonator plate 2 is an XZ′ plane. On this XZ′ plane, the direction parallel to the lateral direction (short side direction) of the crystal resonator plate 2 is the X axis direction, and the direction parallel to the longitudinal direction (long side direction) of the crystal resonator plate 2 is the Z′ axis direction. The AT-cut method is a processing method in which a crystal plate is cut out of synthetic quartz crystal at an angle tilted by 35° 15′ about the X axis from the Z axis, out of the three crystal axes (i.e. an electrical axis (X axis), a mechanical axis (Y axis) and an optical axis (Z axis)) of the synthetic quartz crystal. The X axis of the AT-cut crystal plate equals the crystal axis of the crystal. The Y′ axis and the Z′ axis equal the respective axes that tilt by 35° 15′ from the Y axis and the Z axis out of the crystal axes of the crystal. The Y′ axis direction and the Z′ axis direction correspond to the directions in which the AT-cut crystal is cut out.

A pair of excitation electrodes (i.e. the first excitation electrode 221 and the second excitation electrode 222) is formed, respectively, on the main surfaces 211 and 212 of the crystal resonator plate 2. The crystal resonator plate 2 includes: the vibrating part 22 formed so as to have a substantially rectangular shape; an external frame part 23 surrounding the outer periphery of the vibrating part 22; and a support part 24 that supports the vibrating part 22 by coupling the vibrating part 22 to the external frame part 23. That is, the crystal resonator plate 2 has a configuration in which the vibrating part 22, the external frame part 23 and the support part 24 are integrally formed. Between the external frame part 23 and the vibrating part 22, a penetrating part is formed.

In this embodiment, the support part 24 is provided at only one position between the vibrating part 22 and the external frame part 23. The vibrating part 22 and the support part 24 are formed to have a thickness smaller than a thickness of the external frame part 23. Due to the difference in thickness between the external frame part 23 and the support part 24, the natural frequency of piezoelectric vibration differs between the external frame part 23 and the support part 24. Thus, the external frame part 23 is not likely to resonate with the piezoelectric vibration of the support part 24. The support part 24 is not necessarily formed at one part. The support part 24 may be formed at each of two parts between the vibrating part 22 and the external frame part 23 (for example, both sides in the −Z′ axis direction).

The support part 24 extends (protrudes) from only one corner part positioned in the +X direction and in the −Z′ direction of the vibrating part 22 to the external frame part 23 in the −Z′ direction. Thus, since the support part 24 is disposed on the corner part where displacement of the piezoelectric vibration is relatively small in an outer peripheral edge part of the vibrating part 22, it is possible to prevent leakage of the piezoelectric vibration to the external frame part 23 via the support part 24 compared to the case in which the support part 24 is provided on the position other than the corner part (i.e. central part of the respective sides). Thus, the vibrating part 22 is piezoelectrically vibrated more effectively. It is also possible to reduce stress applied to the vibrating part 22 compared to the case in which two or more support parts 24 are provided. Thus, it is possible to reduce frequency shift of the piezoelectric vibration caused by the stress. Accordingly, it is possible to improve the stability of the piezoelectric vibration.

The first excitation electrode 221 is provided on the first main surface 211 side of the vibrating part 22 while the second excitation electrode 222 is provided on the second main surface 212 side of the vibrating part 22. The first excitation electrode 221 and the second excitation electrode 222 are respectively connected to lead-out wirings (a first lead-out wiring 223 and a second lead-out wiring 224) so that these excitation electrodes are connected to external electrode terminals. The first lead-out wiring 223 is drawn out from the first excitation electrode 221 and connected to a connection bonding pattern 27 formed on the external frame part 23 via the support part 24. The second lead-out wiring 224 is drawn out from the second excitation electrode 222 and connected to a connection bonding pattern 28 formed on the external frame part 23 via the support part 24. Thus, the first lead-out wiring 223 is formed on the first main surface 211 side of the support part 24 while the second lead-out wiring 224 is formed on the second main surface 212 side of the support part 24.

Resonator-plate-side sealing parts to bond the crystal resonator plate 2 respectively to the first sealing member 3 and the second sealing member 4 are provided on the respective main surfaces (i.e. the first main surface 211 and the second main surface 212) of the crystal resonator plate 2. As the resonator-plate-side sealing part on the first main surface 211, a resonator-plate-side first bonding pattern 251 is formed so as to be bonded to the first sealing member 3. As the resonator-plate-side sealing part on the second main surface 212, a resonator-plate-side second bonding pattern 252 is formed so as to be bonded to the second sealing member 4. The resonator-plate-side first bonding pattern 251 and the resonator-plate-side second bonding pattern 252 are each formed on the external frame part 23 so as to have an annular shape in plan view. The first excitation electrode 221 and the second excitation electrode 222 are not electrically connected to the resonator-plate-side first bonding pattern 251 and the resonator-plate-side second bonding pattern 252.

Also, as shown in FIGS. 4 and 5, five through holes are formed in the crystal resonator plate 2 so as to penetrate between the first main surface 211 and the second main surface 212. More specifically, four first through holes 261 are respectively disposed in the four corners (corner parts) of the external frame part 23. A second through hole 262 is disposed in the external frame part 23, on one side in the Z′ axis direction relative to the vibrating part 22 (in FIGS. 4 and 5, on the side in the −Z′ direction). Connection bonding patterns 253 are formed on the respective peripheries of the first through holes 261. Also, on the periphery of the second through hole 262, a connection bonding pattern 254 is formed on the first main surface 211 side while the connection bonding pattern 28 is formed on the second main surface 212 side.

In the first through holes 261 and the second through hole 262, through electrodes are respectively formed along a corresponding inner wall surface of the above through holes so as to establish conduction between the electrodes formed on the first main surface 211 and the second main surface 212. Respective central parts of the first through holes 261 and the second through hole 262 are hollow through parts penetrating between the first main surface 211 and the second main surface 212.

In the crystal resonator plate 2, it is possible to form the following elements by the same process: the first excitation electrode 221; the second excitation electrode 222; the first lead-out wiring 223; the second lead-out wiring 224, the resonator-plate-side first bonding pattern 251; the resonator-plate-side second bonding pattern 252; and the connection bonding patterns 253, 254, 27 and 28. Specifically, each of them can be formed by: a base film deposited on the main surface (the first main surface 211 or the second main surface 212) of the crystal resonator plate 2 by the physical vapor deposition; and a bonding film deposited on the base film by the physical vapor deposition. In this embodiment, the base film is made of Ti (or Cr), and the bonding film is made of Au.

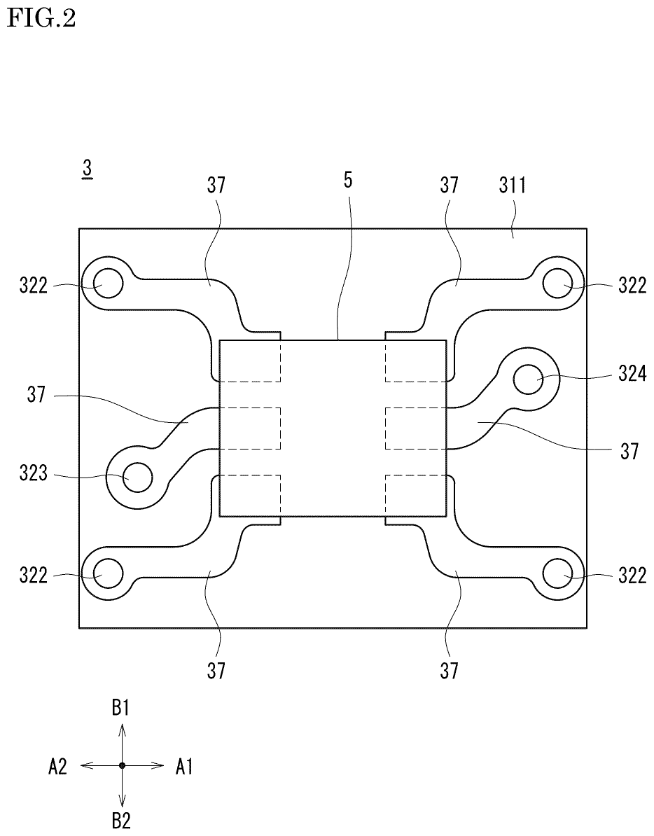

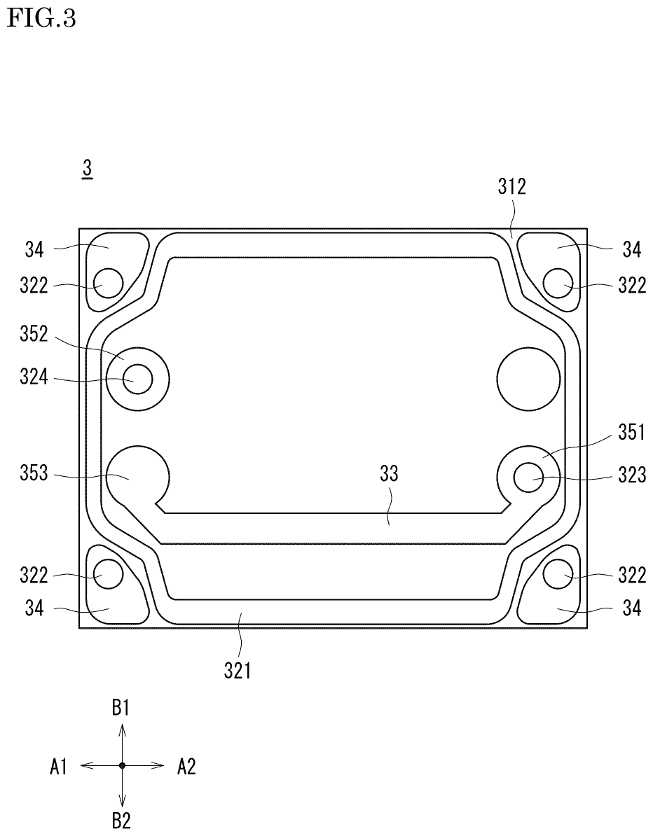

As shown in FIGS. 2 and 3, the first sealing member 3 is a substrate having a rectangular parallelepiped shape that is made of a single crystal wafer. A second main surface 312 (the surface to be bonded to the crystal resonator plate 2) of the first sealing member 3 is formed as a smooth flat surface (mirror finished). As shown in FIG. 2, on a first main surface 311 (the surface on which the IC chip 5 is mounted) of the first sealing member 3, six electrode patterns 37 are formed, which include mounting pads for mounting the IC chip 5 as an oscillation circuit element. The IC chip 5 is bonded to the electrode patterns 37 by the flip chip bonding (FCB) method using a metal bump (for example, Au bump) 38 (see FIG. 1).

As shown in FIGS. 2 and 3, six through holes are formed in the first sealing member 3 so as to be respectively connected to the six electrode patterns 37 and also to penetrate between the first main surface 311 and the second main surface 312. More specifically, four third through holes 322 are respectively disposed in the four corners (corner parts) of the first sealing member 3. Fourth and fifth through holes 323 and 324 are disposed respectively in the A2 direction and in the A1 direction in FIGS. 2 and 3. The A1 direction and the A2 direction in FIGS. 2, 3, 6 and 7 respectively correspond to the −Z′ direction and the +Z′ direction in FIGS. 4 and 5, and the B1 direction and B2 direction in FIGS. 2, 3, 6 and 7 respectively correspond to the −X direction and the +X direction in FIGS. 4 and 5.

In the third through holes 322 and the fourth and fifth through holes 323 and 324, through electrodes (inner wall electrodes) are respectively formed along a corresponding inner wall surface of the above through holes so as to establish conduction between the electrodes formed on the first main surface 311 and the second main surface 312. Respective central parts of the third through holes 322 and the fourth and fifth through holes 323 and 324 are hollow through parts penetrating between the first main surface 311 and the second main surface 312.

On the second main surface 312 of the first sealing member 3, a sealing-member-side first bonding pattern 321 is formed as a sealing-member-side first sealing part so as to be bonded to the crystal resonator plate 2. The sealing-member-side first bonding pattern 321 is formed so as to have an annular shape in plan view.

On the second main surface 312 of the first sealing member 3, connection bonding patterns 34 are respectively formed on the peripheries of the third through holes 322. A connection bonding pattern 351 is formed on the periphery of the fourth through hole 323, and a connection bonding pattern 352 is formed on the periphery of the fifth through hole 324. Furthermore, a connection bonding pattern 353 is formed on the side opposed to the connection bonding pattern 351 in the long axis direction of the first sealing member 3 (i.e. on the side of the A1 direction). The connection bonding pattern 351 and the connection bonding pattern 353 are connected to each other via a wiring pattern 33. The connection bonding pattern 353 is not connected to the connection bonding pattern 352.

In the first sealing member 3, it is possible to form the following elements by the same process: the sealing-member-side first bonding pattern 321; the connection bonding patterns 34, and 351 to 353; and the wiring pattern 33. Specifically, each of them can be formed by: a base film deposited on the second main surface 312 of the first sealing member 3 by the physical vapor deposition; and a bonding film deposited on the base film by the physical vapor deposition. In this embodiment, the base film is made of Ti (or Cr), and the bonding film is made of Au.

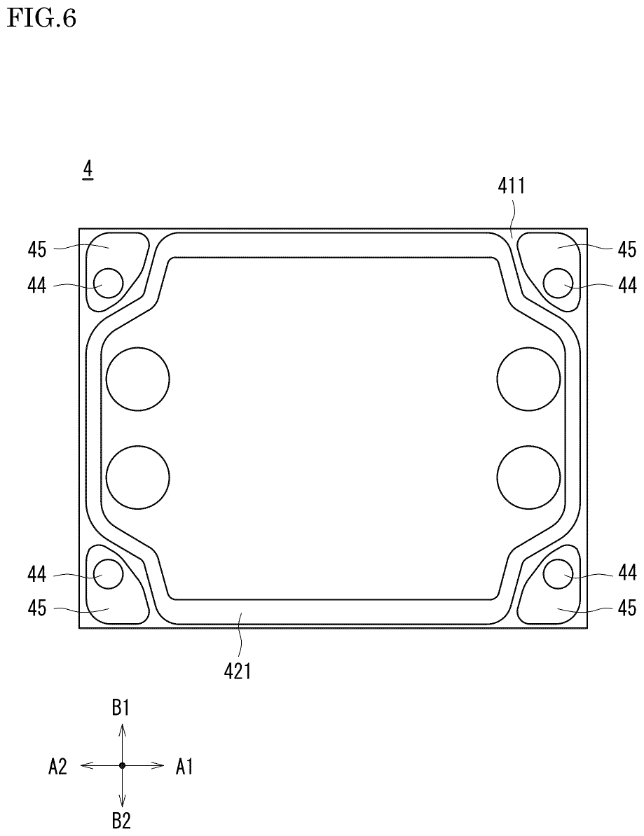

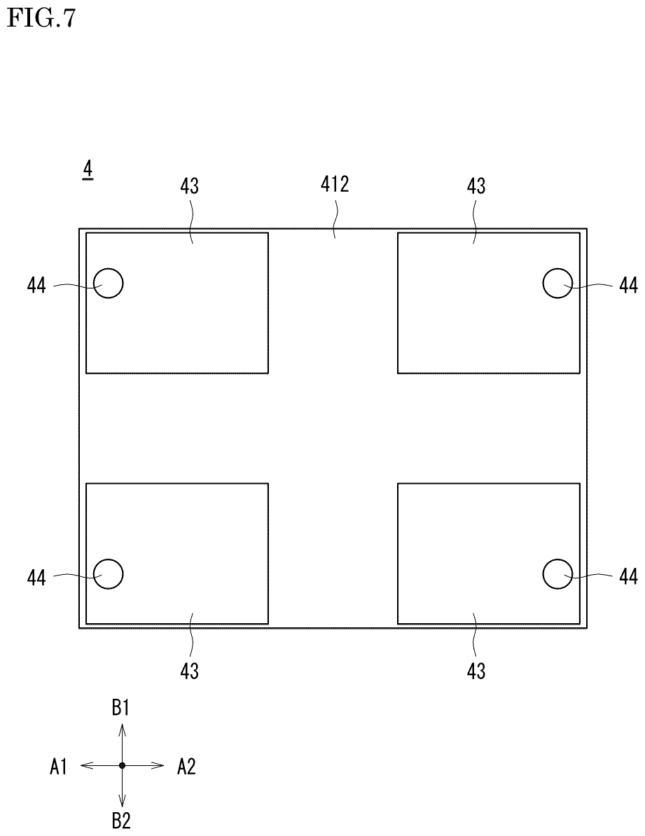

As shown in FIGS. 6 and 7, the second sealing member 4 is a substrate having a rectangular parallelepiped shape that is made of a single crystal wafer. A first main surface 411 (the surface to be bonded to the crystal resonator plate 2) of the second sealing member 4 is formed as a smooth flat surface (mirror finished). On the first main surface 411 of the second sealing member 4, a sealing-member-side second bonding pattern 421 is formed as a sealing-member-side second sealing part so as to be bonded to the crystal resonator plate 2. The sealing-member-side second bonding pattern 421 is formed so as to have an annular shape in plan view.

Four external electrode terminals 43, which are electrically connected to the outside, are formed on a second main surface 412 (the outer main surface not facing the crystal resonator plate 2) of the second sealing member 4. The external electrode terminals 43 are respectively located at four corners (corner parts) of the second sealing member 4.

As shown in FIGS. 6 and 7, four through holes are formed in the second sealing member 4 so as to penetrate between the first main surface 411 and the second main surface 412. More specifically, four sixth through holes 44 are respectively disposed in the four corners (corner parts) of the second sealing member 4. In the sixth through holes 44, through electrodes are respectively formed along a corresponding inner wall surface of the above through holes so as to establish conduction between the electrodes formed on the first main surface 411 and the second main surface 412. Respective central parts of the sixth through holes 44 are hollow through parts penetrating between the first main surface 411 and the second main surface 412. On the first main surface 411 of the second sealing member 4, connection bonding patterns 45 are respectively formed on the peripheries of the sixth through holes 44.

In the second sealing member 4, it is possible to form the following elements by the same process: the sealing-member-side second bonding pattern 421; and the connection bonding patterns 45. Specifically, each of them can be formed by: a base film deposited on the first main surface 411 of the second sealing member 4 by the physical vapor deposition; and a bonding film deposited on the base film by the physical vapor deposition. In this embodiment, the base film is made of Ti (or Cr), and the bonding film is made of Au.

In the crystal oscillator 101 including the crystal resonator plate 2, the first sealing member 3 and the second sealing member 4, the crystal resonator plate 2 and the first sealing member 3 are subjected to the diffusion bonding in a state in which the resonator-plate-side first bonding pattern 251 and the sealing-member-side first bonding pattern 321 are superimposed on each other, and the crystal resonator plate 2 and the second sealing member 4 are subjected to the diffusion bonding in a state in which the resonator-plate-side second bonding pattern 252 and the sealing-member-side second bonding pattern 421 are superimposed on each other, thus, the package 12 having the sandwich structure shown in FIG. 1 is produced. Accordingly, the internal space of the package 12, i.e. the space to house the vibrating part 22 is hermetically sealed.

In this case, the respective connection bonding patterns as described above are also subjected to the diffusion bonding in a state in which they are each superimposed on the corresponding connection bonding pattern. Such bonding between the connection bonding patterns allows electrical conduction of the first excitation electrode 221, the second excitation electrode 222, the IC chip 5 and the external electrode terminals 43 of the crystal oscillator 101.

More specifically, the first excitation electrode 221 is connected to the IC chip 5 via the first lead-out wiring 223, a bonding part between the connection bonding pattern 27 and the connection bonding pattern 353, the wiring pattern 33, the connection bonding pattern 351, the through electrode in the fourth through hole 323, and the electrode pattern 37 in this order. The second excitation electrode 222 is connected to the IC chip 5 via the second lead-out wiring 224, the connection bonding pattern 28, the through electrode in the second through hole 262, a bonding part between the connection bonding pattern 254 and the connection bonding pattern 352, the through electrode in the fifth through hole 324, and the electrode pattern 37 in this order. Also, the IC chip 5 is connected to the external electrode terminals 43 via the electrode patterns 37, the through electrodes in the third through holes 322, bonding parts between the connection bonding patterns 34 and the connection bonding patterns 253, the through electrodes in the first through holes 261, bonding parts between the connection bonding patterns 253 and the connection bonding patterns 45, and the through electrodes in the sixth through holes 44 in this order.

In the package 12 having the sandwich structure produced as described above, the first sealing member 3 and the crystal resonator plate 2 have a gap of not more than 1.00 μm. The second sealing member 4 and the crystal resonator plate 2 have a gap of not more than 1.00 μm. That is, the thickness of the bonding part between the first sealing member 3 and the crystal resonator plate 2 is not more than 1.00 μm, and the thickness of the bonding part between the second sealing member 4 and the crystal resonator plate 2 is not more than 1.00 μm (specifically, the thickness in the Au—Au bonding in this embodiment is 0.15 to 1.00 μm). As a comparative example, the conventional metal paste sealing material containing Sn has a thickness of 5 to 20 μm.

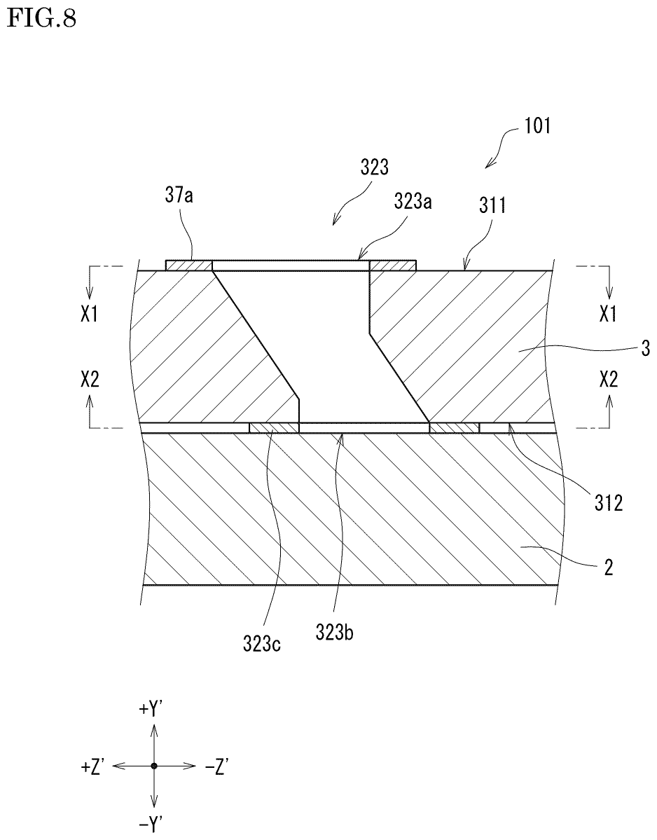

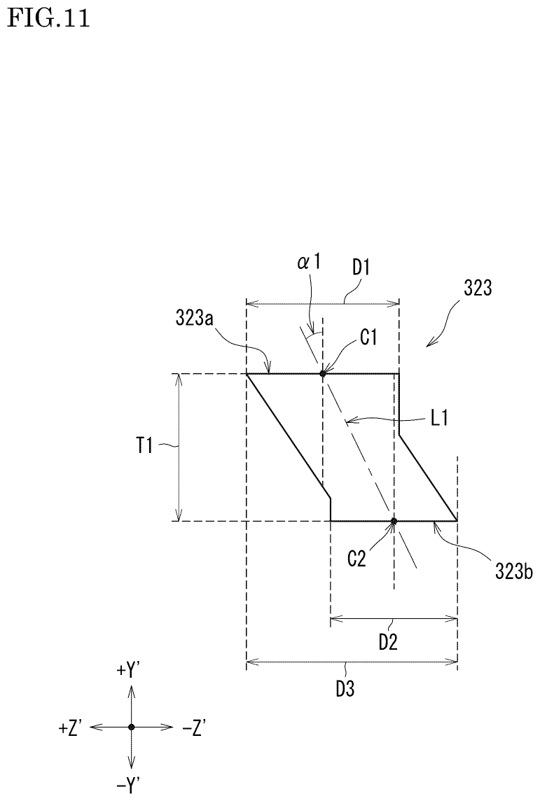

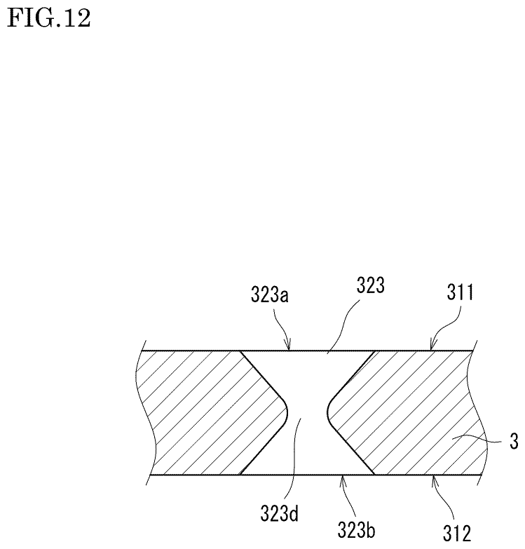

In this embodiment as described above, the hermetic sealing in the crystal oscillator 101 is realized by: sandwiching the crystal resonator plate 2 including the first and second excitation electrodes 221 and 222 by the first and second sealing members (crystal sealing plates) 3 and 4 placed respectively above and below the crystal resonator plate 2; and bonding the respective sealing parts to the corresponding sealing part. The first sealing member 3 is provided with the fourth and fifth through holes 323 and 324 that penetrate between the first main surface 311 on the outer surface side and the second main surface 312 on the sealing surface side. Each of the fourth and fifth through holes 323 and 324 is provided with: the through electrode (inner wall electrode) formed on the corresponding inner wall surface; an outer-surface-side opening surrounding electrode formed on the periphery of an opening in the outer surface side; and a sealing-surface-side opening surrounding electrode formed on the periphery of an opening in the sealing surface side. Also, the fourth and fifth through holes 323 and 324 each have the hollow penetrating part. In each of the fourth and fifth through holes 323 and 324, the opening area of the opening in the outer surface side is larger than the opening area of the opening in the sealing surface side, and furthermore the width of the sealing-surface-side opening surrounding electrode is larger than the width of the outer-surface-side opening surrounding electrode in the Z′ axis direction. Now, this configuration is described in detail referring to FIGS. 8 to 12. Here, the configuration of the fourth through hole 323 as shown in FIGS. 8 to 12 is exemplarily described, however, the fifth through hole 324 also has the same configuration. In FIG. 11, only the cross-sectional shape of the fourth through hole 323 is shown, and thus the other components are omitted. In addition, the electrodes and the like formed on the periphery of the fourth through hole 323 are also omitted from FIG. 12.

The first sealing member 3 as the crystal sealing plate is made of an AT-cut crystal plate. This rectangular-shaped crystal plate is subjected to wet etching so that six through holes are formed (see FIGS. 2 and 3). When the wet etching is performed to both the first main surface 311 and the second main surface 312 of the first sealing member 3, the through holes each having a cross-section as shown in FIGS. 8 and 12 are formed in the first sealing member 3, because of crystal anisotropy. FIG. 8 shows a cross-sectional view of the fourth through hole 323, which is cut by the plane parallel to the Y′Z′ plane. FIG. 12 shows a cross-sectional view of the fourth through hole 323, which is cut by the plane parallel to the XY′ plane. As shown in FIGS. 8 and 12, the fourth through hole 323 does not have a simple cylindrical shape, but has a shape as a result of the wet etching performed to the first sealing member 3 from both the first main surface 311 and the second main surface 312 thereof. In the cross-sectional shape shown in FIG. 8, the shape of the fourth through hole 323 is inclined such that the lower (i.e. in the −Y′ direction) it extends the closer it is shifted to the internal space of the package 12 (i.e. in the −Z′ direction in FIG. 8). On the other hand, in FIG. 12, the cross-sectional shape of the fourth through hole 323 is a shape substantially along the vertical direction.

In this embodiment, an outer-surface-side opening surrounding electrode 37a, which is formed on the periphery of an opening 323a in the side of the first main surface 311 of the fourth through hole 323, is provided on an end part of the above-described electrode pattern 37. A sealing-surface-side opening surrounding electrode 323c, which is formed on the periphery of an opening 323b in the side of the second main surface 312, is made by the diffusion bonding (Au—Au bonding) of the above-described connection bonding pattern 351 (see FIG. 3) and the connection bonding pattern 255 (see FIG. 4) formed on the first main surface 211 of the crystal resonator plate 2. The sealing-surface-side opening surrounding electrode 323c has a configuration including a front surface main electrode layer made of Au and a base electrode layer made of Ti.

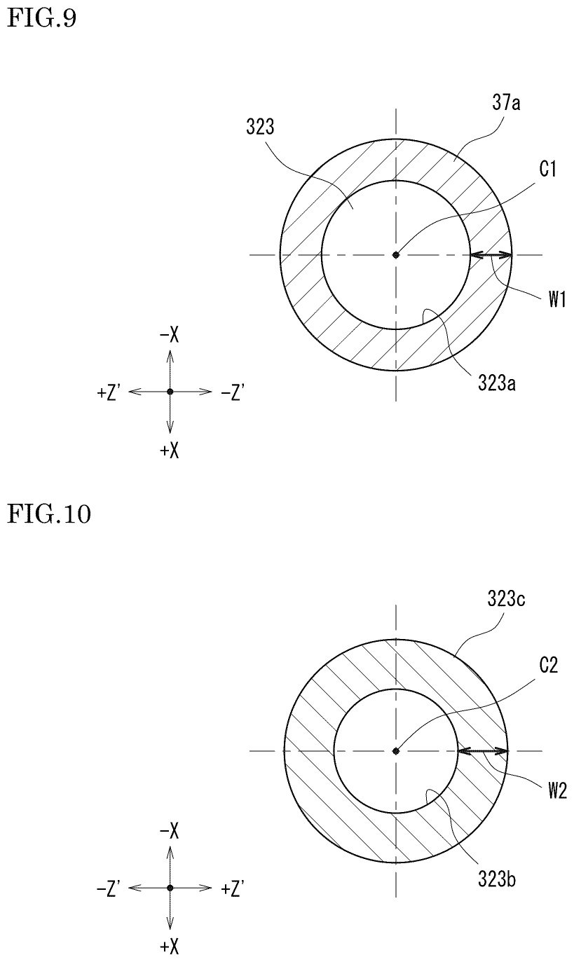

The opening area of the opening 323a in the side of the first main surface 311 of the fourth through hole 323 (i.e. the area of the part inside the hatching part of FIG. 9) is larger than the opening area of the opening 323b in the side of the second main surface 312 (i.e. the area of the part inside the hatching part of FIG. 10). The width W2 of the sealing-surface-side opening surrounding electrode 323c (FIG. 10) is larger than the width W1 of the outer-surface-side opening surrounding electrode 37a (FIG. 9) in the Z′ axis direction. The width W2 of the sealing-surface-side opening surrounding electrode 323c (FIG. 10) is also larger than the width W1 of the outer-surface-side opening surrounding electrode 37a (FIG. 9) in the X axis direction. In this embodiment, the width W2 of the sealing-surface-side opening surrounding electrode 323c (FIG. 10) is larger than the width W1 of the outer-surface-side opening surrounding electrode 37a (FIG. 9) in the entire circumference.

In the fourth through hole 323 of this embodiment, since the width W2 of the sealing-surface-side opening surrounding electrode 323c is larger than the width W1 of the outer-surface-side opening surrounding electrode 37a, it is possible to prevent the corrosion of the base electrode layer (Ti layer) of the sealing-surface-side opening surrounding electrode 323c from progressing and thus reaching the internal space of the package 12, compared to the case in which the width W1 of the outer-surface-side opening surrounding electrode 37a is the same as the width W2 of the sealing-surface-side opening surrounding electrode 323c. Thus, the hermeticity of the internal space of the package 12 can be maintained as much as possible. Furthermore, in the fourth through hole 323, since the width W1 of the outer-surface-side opening surrounding electrode 37a is smaller than the width W2 of the sealing-surface-side opening surrounding electrode 323c, it is possible to easily design the wiring on the first main surface 311 of the first sealing member 3 compared to the case in which the width W1 of the outer-surface-side opening surrounding electrode 37a is the same as the width W2 of the sealing-surface-side opening surrounding electrode 323c, which contributes to the miniaturization of the package 12.

The width W1 of the outer-surface-side opening surrounding electrode 37a and the width W2 of the sealing-surface-side opening surrounding electrode 323c are preferably in the range of 10 to 30 μm. When the width W1 of the outer-surface-side opening surrounding electrode 37a and the width W2 of the sealing-surface-side opening surrounding electrode 323c are less than 10 μm, the sealing stability may be degraded. On the other hand, when the width W1 of the outer-surface-side opening surrounding electrode 37a and the width W2 of the sealing-surface-side opening surrounding electrode 323c are more than 30 μm, the wiring design may be difficult on the first main surface 311 and the second main surface 312 of the first sealing member 3, which results in difficulty in miniaturizing the package 12.

If the opening area of the opening 323a in the side of the first main surface 311 of the fourth through hole 323 is the same as the opening area of the opening 323b in the side of the second main surface 312, it is necessary to increase the total volume of the components including the fourth through hole 323 and the surrounding electrodes (i.e. the outer-surface-side opening surrounding electrode 37a and the sealing-surface-side opening surrounding electrode 323c) in order to ensure the width W2 of the sealing-surface-side opening surrounding electrode 323c. In contrast to the above, in this embodiment, the opening areas of the openings 323a and 323b of the fourth through hole 323 have a magnitude relationship. That is, the opening area of the opening 323b in the side of the second main surface 312 is smaller than the opening area of the opening 323a in the side of the first main surface 311. Thus, there is an enough space around the fourth through hole 323 for easily ensuring the width W2 of the sealing-surface-side opening surrounding electrode 323c, which leads to a configuration advantageous for the miniaturization without unnecessarily increasing the total volume of the components including the fourth through hole 323 and the surrounding electrodes. As a result, since the width W2 of the sealing-surface-side opening surrounding electrode 323c can be increased, the area of the sealing part by the sealing-surface-side opening surrounding electrode 323c does not become too small. Therefore, the area can be stably ensured, and thus, the corrosion can be prevented from progressing compared to the case in which the area of the sealing part cannot be ensured.

When the wet etching is performed to the AT-cut crystal resonator plate, the fourth through hole 323 is inclined in the Z′ axis direction because of crystal anisotropy, which sometimes causes difficulty in sufficiently ensuring the width of the surrounding electrode as a result of deviation from the design. In contrast, in this embodiment, since the sealing-surface-side opening surrounding electrode 323c is largely formed in the Z′ axis direction, it is possible to easily handle the above problem, which contributes to stability of heremeticity and of conductivity.

Also in this embodiment, the center C1 of the opening 323a in the side of the first main surface 311 of the fourth through hole 323 (FIG. 9) is superimposed, in plan view, on a substantial opening end of the opposed opening 323b in the side of the second main surface 312 of the fourth through hole 323. The center C2 of the opening 323b in the side of the second main surface 312 of the fourth through hole 323 (FIG. 10) is superimposed, in plan view, on a substantial opening end of the opposed opening 323a in the side of the first main surface 311 of the fourth through hole 323. The center C1 of the opening 323a in the side of the first main surface 311 of the fourth through hole 323 (FIG. 9) is defined by the central position of the length of the opening 323a in the X axis direction and by the central position of the length of the opening 323a in the Z′ axis direction. The substantial opening end of the opening 323a preferably means the region in the range not more than 10 μm from the opening end of the opening 323a. The substantial opening end of the opening 323b preferably means the region in the range not more than 10 μm from the opening end of the opening 323b. In this way, it is possible to reliably form the fourth through hole 323 in the first sealing member 3 by wet etching without unnecessarily increasing the volume of the fourth through hole 323, which contributes to the miniaturization of the package 12.

Also, the fourth through hole 323 includes, in the central part thereof in the thickness direction of the first sealing member 3, a central opening 323d (FIG. 12) having the smallest opening cross-sectional area. In this embodiment, the central opening 323d is provided in the substantially central part in the thickness direction of the first sealing member 3. The center C1 of the opening 323a in the side of the first main surface 311 of the fourth through hole 323 (FIG. 9) is superimposed, in plan view, on the central opening 323d. The center C2 of the opening 323b in the side of the second main surface 312 of the fourth through hole 323 (FIG. 10) is superimposed, in plan view, on the central opening 323d. In this way, it is possible to reliably form the fourth through hole 323 in the first sealing member 3 by wet etching without unnecessarily increasing the volume of the fourth through hole 323, which contributes to the miniaturization of the package 12. Furthermore, it is possible to prevent break or the like of the through electrode, the outer-surface-side opening surrounding electrode 37a, and the sealing-surface-side opening surrounding electrode 323c, of the fourth through hole 323.

Furthermore, the outer peripheral end (in this case, the outer peripheral end in the −Z′ direction) of the sealing-surface-side opening surrounding electrode 323c of the fourth through hole 323 is located outside the opening end of the opening 323a in the side of the first main surface 311 of the fourth through hole 323. In this ways, since there is no gap between the sealing members, the pressure is vertically applied from the first main surface 311 to the surface of the sealing-surface-side opening surrounding electrode 323c at the time of pressurization, which leads to more reliable Au—Au bonding and also to stable hermeticity of the internal space of the package 12.

Here, from the viewpoint of stably forming the fourth through hole 323 in the first sealing member 3 by wet etching, the size and the like of the fourth through hole 323 is set as described below. Referring to FIG. 11, when the thickness T1 of the first sealing member 3 is 40 μm, D1+D2 preferably falls in the range of 80 to 120 μm, where D1 represents the length of the opening 323a in the side of the first main surface 311 of the fourth through hole 323 in the Z′ axis direction (i.e. the opening diameter) and D2 represents the length of the opening 323b in the side of the second main surface 312 of the fourth through hole 323 in the Z′ axis direction (i.e. the opening diameter). It is preferable that the inclination angle α1 of the virtual line L1 connecting the center C1 of the opening 323a in the side of the first main surface 311 of the fourth through hole 323 and the center C2 of the opening 323b in the side of the second main surface 312 with respect to the vertical direction falls in the range of 10° to 30°. It is preferable that the length D3 in the Z′ axis direction from the opening end of the opening 323a in the side of the first main surface 311 of the fourth through hole 323 in the +Z′ direction to the opening end of the opening 323b in the side of the second main surface 312 in the −Z′ direction falls in the range of 55 to 75 μm.

The present invention may be embodied in other forms without departing from the gist or essential characteristics thereof. The foregoing embodiments are therefore to be considered in all respects as illustrative and not limiting. The scope of the invention is indicated by the appended claims rather than by the foregoing description, and all modifications and changes that come within the meaning and range of equivalency of the claims are intended to be embraced therein.

In the above-described embodiment, the width W2 of the sealing-surface-side opening surrounding electrode 323c of the fourth through hole 323 (FIG. 10) is larger than the width W1 of the outer-surface-side opening surrounding electrode 37a (FIG. 9) in the entire circumference. However, the present invention is not limited thereto. The width W2 of the sealing-surface-side opening surrounding electrode 323c of the fourth through hole 323 (FIG. 10) is only required to be larger than the width W1 of the outer-surface-side opening surrounding electrode 37a (FIG. 9) at least in the X axis direction or in the Z′ axis direction.

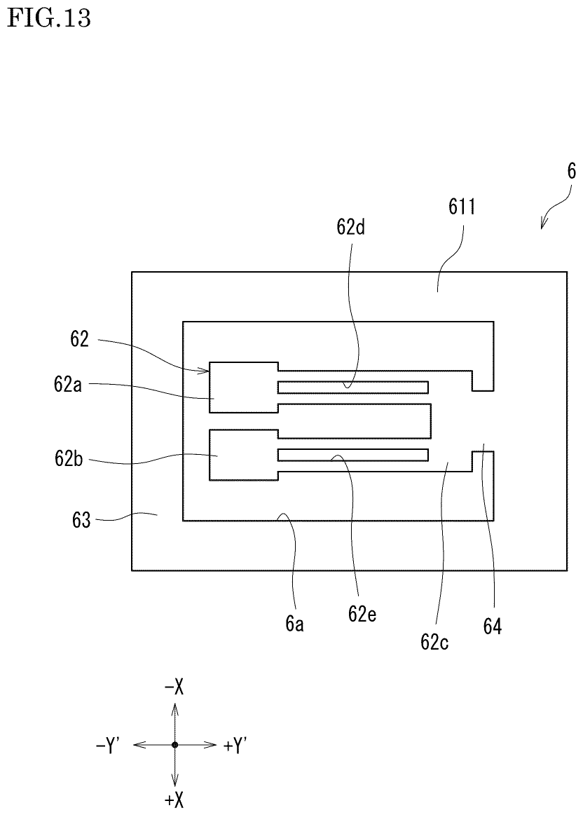

In the above-described embodiment, the AT-cut crystal resonator plate that causes thickness shear vibration is used as the crystal resonator plate. However, other crystal resonator plates (for example, an SC-cut crystal resonator plate and a Z-cut crystal resonator plate (Z-cut quartz plate)) may be used. For example, it is possible to apply the present invention to a piezoelectric resonator device including a tuning fork-type crystal resonator plate made of a Z-cut crystal resonator plate as shown in FIG. 13.

A tuning fork-type crystal resonator plate 6 shown in FIG. 13 includes: a vibrating part 62 formed so as to have a tuning folk shape; an external frame part 63 surrounding the outer periphery of the vibrating part 62; and a support part 64 that supports the vibrating part 62 by coupling the vibrating part 62 to the external frame part 63. The tuning fork-type crystal resonator plate 6 has a configuration in which the vibrating part 62, the external frame part 63 and the support part 64 are integrally formed. Between the external frame part 63 and the vibrating part 62, a penetrating part 6a is formed. FIG. 13 shows a first main surface 611 side of the tuning fork-type crystal resonator plate 6. Also, from FIG. 13, the elements such as the first and second excitation electrodes formed on the vibrating part 62 and the lead-out wirings connected to the first and second excitation electrodes are omitted.

The vibrating part 62 includes: two leg parts 62a and 62b extending in the Y′ axis direction; and a base part 62c to which both end parts of the leg parts 62a and 62b are connected. The leg parts 62a and 62b each extend from an end part of the base part 62c in the −Y′ direction toward the −Y′ direction. The leg parts 62a and 62b are respectively provided with recess parts 62d and 62e on both the first main surface 611 and the second main surface thereof, so that the cross section of each of the leg parts 62a and 62b has a substantially H-shape. The support part 64 is provided at only one position between the vibrating part 62 and the external frame part 63. The support part 64 extends, from a center part of the base part 62c in the X axis direction at an end part of the base part 62c of the vibrating part 62 in the +Y′ direction, to the external frame part 63 in the +Y′ direction.

In the above-described embodiment, the first sealing member 3 is bonded to the crystal resonator plate 2, and furthermore the second sealing member 4 is bonded to the crystal resonator plate 2, both by metal-to-metal bonding such as Au—Au bonding. However, the bonding of the first sealing member 3 to the crystal resonator plate 2 as well as the second sealing member 4 to the crystal resonator plate 2 may be performed by brazing.

In the above-described embodiment, the present invention is applied to the fourth and the fifth through holes 323 of the first sealing member 3. However, the present invention may also be applied to the third through holes 322 formed in the four corners of the first sealing member 3. Also, the present invention may be applied to the sixth through holes 44 of the second sealing member 4. In the above-described embodiment, the first sealing member 3 and the second sealing member 4 as the crystal sealing plates are each made of an AT-cut crystal plate. However, the present invention is not limited thereto. The first sealing member 3 and the second sealing member 4 may be made of another kind of crystal resonator plate (for example, an SC-cut crystal plate or a Z-cut crystal plate), or also may be made of glass.

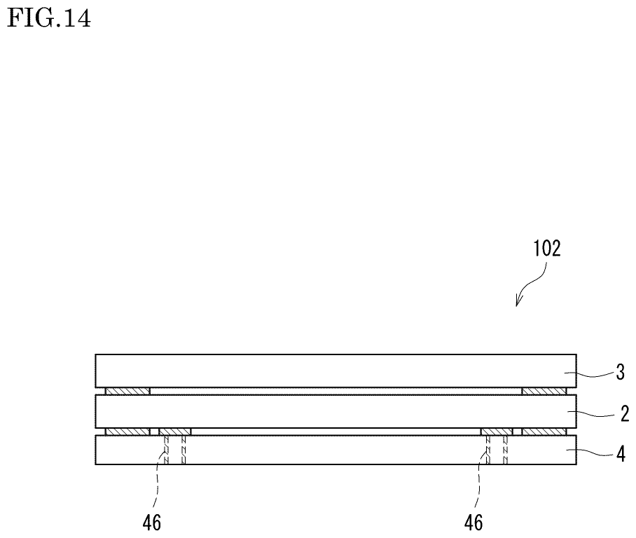

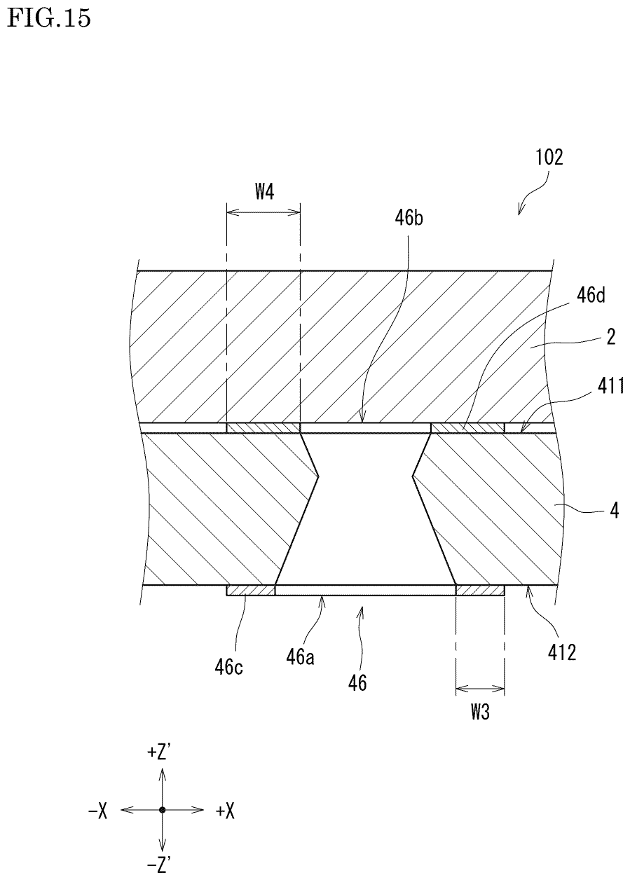

As exemplarily shown in FIGS. 14 and 15, the present invention can be applied to a crystal resonator 102 (piezoelectric resonator device) having a configuration in which the through holes are formed only in the second sealing member 4. In this crystal resonator 102, the crystal resonator plate 2 is made of an AT-cut crystal resonator plate while the first sealing member 3 and the second sealing member 4 as the crystal sealing plates are each made of a Z-cut crystal plate.

In the crystal resonator 102, the crystal resonator plate 2 is bonded to the first sealing member 3, and also the crystal resonator plate 2 is bonded to the second sealing member 4. Thus, a package having a sandwich structure is formed so as to have a substantially rectangular parallelepiped shape. A vibrating part of the crystal resonator plate 2 is hermetically sealed in the internal space of the package. The crystal resonator plate 2, the first sealing member 3 and the second sealing member 4 have configurations respectively similar to the crystal resonator plate 2, the first sealing member 3 and the second sealing member 4 of the above-described embodiment (see FIGS. 2 to 7). However, the crystal resonator 102 differs from the above-described embodiment in that through holes 46 are formed only in the second sealing member 4. In this embodiment, the crystal resonator plate 2 and the first sealing member 3 have no through holes, and only the second sealing member 4 has the through holes 46 formed in the four corners (corner parts) thereof.

As shown in FIG. 15 specifically, the through hole 46 is formed in the second sealing member 4 so as to penetrate between the second main surface 412 on the outer surface side and the first main surface 411 on the sealing surface side. The through hole 46 is provided with: a through electrode (not shown) formed on an inner wall surface; an outer-surface-side opening surrounding electrode 46c formed on the periphery of an opening 46a in the outer surface side; and a sealing-surface-side opening surrounding electrode 46d formed on the periphery of an opening 46b in the sealing surface side. Also, the through hole 46 has a hollow penetrating part.

In this embodiment, the second sealing member 4 as the crystal sealing plate is made of a Z-cut crystal plate. This rectangular-shaped crystal plate is subjected to wet etching so that the through holes 46 are formed. When the wet etching is performed to both the first main surface 411 and the second main surface 412 of the second sealing member 4, the through holes 46 each having a cross-section as shown in FIG. 15 are formed in the second sealing member 4, because of crystal anisotropy. FIG. 15 shows a cross-sectional view of the through hole 46, which is cut by the plane parallel to the XZ′ plane. As shown in FIG. 15, the through hole 46 does not have a simple cylindrical shape, but has a shape as a result of the wet etching performed to the second sealing member 4 from both the first main surface 411 and the second main surface 412 thereof. Since the Z-cut crystal plate has a crystal orientation different from that of the AT-cut crystal plate, the shape of the through hole 46 formed by wet etching is also different from that of the fourth through hole 323 (see FIG. 8) of the above-described embodiment. Specifically, the opening area of the opening 46a in the outer surface side of the through hole 46 is larger than the opening area of the opening 46b in the sealing surface side. The width W4 of the sealing-surface-side opening surrounding electrode 46d is larger than the width W3 of the outer-surface-side opening surrounding electrode 46c in the X axis direction. In addition to the above, the present invention is not necessarily applied to the piezoelectric resonator device having the three-layer structure as described above. The present invention can also be applied to a piezoelectric resonator device having the structure with four or more layers.

This application claims priority based on Patent Application No. 2022-121680 filed in Japan on Jul. 29, 2022. The entire contents thereof are hereby incorporated in this application by reference.

### DESCRIPTION OF THE REFERENCE NUMERALS

101 Crystal oscillator (piezoelectric resonator device)
2 Crystal resonator plate (piezoelectric resonator plate)
3 First sealing member (crystal sealing plate)
37a Outer-surface-side opening surrounding electrode
221 First excitation electrode
222 Second excitation electrode
311 First main surface
312 Second main surface
323 Fourth through hole (through hole)
323a Opening in first main surface side
323b Opening in second main surface side
323c Sealing-surface-side opening surrounding electrode
W1 Width of outer-surface-side opening surrounding electrode
W2 Width of sealing-surface-side opening surrounding electrode

1. A piezoelectric resonator device in which a crystal resonator plate having excitation electrodes thereon is sandwiched by crystal sealing plates placed respectively above and below the crystal resonator plate so as to bond and hermetically seal respective sealing parts to each other, wherein
each or any of the crystal sealing plates includes a through hole penetrating between an outer surface side and a sealing surface side,
the through hole is provided with: an inner wall electrode formed on an inner wall surface; an outer-surface-side opening surrounding electrode formed on a periphery of an opening in the outer surface side; and a sealing-surface-side opening surrounding electrode formed on a periphery of an opening in the sealing surface side,
the through hole includes a hollow penetrating part,
an opening area of the opening in the outer surface side of the through hole is larger than an opening area of the opening in the sealing surface side, and
a width of the sealing-surface-side opening surrounding electrode is larger than a width of the outer-surface-side opening surrounding electrode in a Z′ axis direction.

2. The piezoelectric resonator device according to claim 1, wherein
the width of the sealing-surface-side opening surrounding electrode is larger than the width of the outer-surface-side opening surrounding electrode in an X axis direction.

3. A piezoelectric resonator device in which a crystal resonator plate having excitation electrodes thereon is sandwiched by crystal sealing plates placed respectively above and below the crystal resonator plate so as to bond and hermetically
seal respective sealing parts to each other, wherein each or any of the crystal sealing plates includes a through hole penetrating between an outer surface side and a sealing surface side,
the through hole is provided with: an inner wall electrode formed on an inner wall surface; an outer-surface-side opening surrounding electrode formed on a periphery of an opening in the outer surface side; and a sealing-surface-side opening surrounding electrode formed on a periphery of an opening in the sealing surface side,
the through hole includes a hollow penetrating part,
an opening area of the opening in the outer surface side of the through hole is larger than an opening area of the opening in the sealing surface side, and
a width of the sealing-surface-side opening surrounding electrode is larger than a width of the outer-surface-side opening surrounding electrode in an X axis direction.

4. The piezoelectric resonator device according to claim 1, wherein
the bonding is Au—Au diffusion bonding, and
the sealing-surface-side opening surrounding electrode includes a front surface main electrode layer made of Au and a base electrode layer made of Ti.

5. The piezoelectric resonator device according to claim 1, wherein
a center of the opening in the outer surface side of the through hole is superimposed on a substantial opening end in the sealing surface side, which is opposed to the outer surface side, of the through hole, and
a center of the opening in the sealing surface side of the through hole is superimposed on a substantial opening end in the outer surface side, which is opposed to the sealing surface side, of the through hole.

6. The piezoelectric resonator device according to claim 1, wherein
a central opening having the smallest opening cross-sectional area is provided in a central part of the through hole in a thickness direction of each or any of the crystal sealing plates, and
a center of the opening in the outer surface side of the through hole is superimposed on the central opening, and furthermore a center of the opening in the sealing surface side of the through hole is superimposed on the central opening.

7. The piezoelectric resonator device according to claim 1, wherein
an outer peripheral end of the sealing-surface-side opening surrounding electrode is located outside an opening end in the outer surface side of the through hole.

8. The piezoelectric resonator device according to claim 3, wherein
the bonding is Au—Au diffusion bonding, and
the sealing-surface-side opening surrounding electrode includes a front surface main electrode layer made of Au and a base electrode layer made of Ti.

9. The piezoelectric resonator device according to claim 3, wherein
a center of the opening in the outer surface side of the through hole is superimposed on a substantial opening end in the sealing surface side, which is opposed to the outer surface side, of the through hole, and
a center of the opening in the sealing surface side of the through hole is superimposed on a substantial opening end in the outer surface side, which is opposed to the sealing surface side, of the through hole.

10. The piezoelectric resonator device according to claim 3, wherein
a central opening having the smallest opening cross-sectional area is provided in a central part of the through hole in a thickness direction of each or any of the crystal sealing plates, and
a center of the opening in the outer surface side of the through hole is superimposed on the central opening, and furthermore a center of the opening in the sealing surface side of the through hole is superimposed on the central opening.

11. The piezoelectric resonator device according to claim 3, wherein
an outer peripheral end of the sealing-surface-side opening surrounding electrode is located outside an opening end in the outer surface side of the through hole.
